(19) United States
(12) Patent Application Publication
(10) Pub. No.: US 2015/0380170 A1
(43) Pub. Date: Dec. 31, 2015

(54) Mesoporous Structure Solar Cell with Siloxane Barrier

(71) Applicant: Sharp Laboratories of America, Inc., Camas, WA (US)

(72) Inventors: Alexey Koposov, Vancouver, WA (US); Changqing Zhan, Vancouver, WA (US); Wei Pan, Vancouver, WA (US)

(21) Appl. No.: 14/320,702

(22) Filed: Jul. 1, 2014

Related U.S. Application Data
(63) Continuation-in-part of application No. 14/320,488, filed on Jun. 30, 2014.

(51) Int. Cl. H01G 9/20; H01L 51/00

(52) U.S. Cl. CPC H01G 9/2031; H01G 9/204; H01G 9/2027; H01G 9/2059; H01L 51/0084

(57) ABSTRACT

A method is provided for forming a mesoporous-structured solar cell with a silane or siloxane barrier. The method forms a transparent conductive electrode overlying a transparent substrate. A non-mesoporous layer of a first metal oxide overlies the transparent conductive electrode, with a mesoporous layer of a second metal oxide overlying the non-mesoporous layer of first metal oxide. An aminoalkoxysilane layer overlies the mesoporous layer of second metal oxide. Over the aminoalkoxysilane layer is deposited a semiconductor absorber layer comprising organic and inorganic components. Using the aminoalkoxysilane linker, the mesoporous layer of second metal oxide is linked to the semiconductor absorber layer. A hole-transport material (HTM) layer is formed overlying the semiconductor absorber layer, and a metal electrode overlies the HTM layer. A mesoporous-structured solar cell with a silane or siloxane barrier is also provided.

### RELATED APPLICATIONS

This application is a Continuation-in-part of a patent application entitled, SURFACE-PASSIVATED MESOPOROUS STRUCTURE SOLAR CELL, invented by Changqing Zhan et al., U.S. Ser. No. 14/320,488, filed Jun. 30, 2014, attorney docket No. SLA3383, which is incorporated herein by reference.

### BACKGROUND OF THE INVENTION

1. Field of the Invention

This invention generally relates to solar cells and, more particularly, to a mesoporous-structure solar cell using a siloxane barrier.

2. Description of the Related Art

As evolved from dye-sensitized solar cells (DSSCs or DSCs), perovskite-sensitized solar-cells have recently attracted a great deal attention with a record high efficiency breakthrough (>17%) based upon low cost organometal trihalide perovskite absorbers. It has been suggested that with optimization of the cell structure, light absorber, and hole conducting material, this technology could advance to an efficiency that surpasses that of copper indium gallium (di)selenide (CIGS) (20%) and approaches crystalline silicon (25%). Conventional perovskite based solar cells use two common types of architecture: flat and mesoscopic. With the flat architecture, one absorber layer is deposited directly on a flat (planar) titanium oxide (TiO₂) surface forming a thin film, in a fashion similar to thin film solar cells. The second approach adopts a configuration similar to solid dye-sensitized solar cells.

FIG. 1 is a partial cross-sectional view of a perovskite solar cell structure (prior art). As depicted in the figure, a mesostructured perovskite-based solar cell structure is composed of a FTO glass substrate 102 as an anode, a thin layer of compact (planar) TiO₂ layer 104 deposited by spray paralysis, followed by about 300-500 nanometers (nm) of mesoporous spin-coated or printed TiO₂ 106, which serves both as the electron transporter and the “scaffold” on which the perovskite absorber 108 is coated using a solution-based process. A hole transport material (HTM) 110 (e.g., spiro-OMeTAD) is coated over the perovskite absorber 108, and on top of the solar cell is a gold electrode 112 formed by evaporation.

The mesoporous TiO₂ electrode 106 has long been the most commonly used electron transporter material since the advent of liquid DSC. This porous TiO₂ structure provides sufficient internal surface area to which dye molecules can attach and, therefore, maximizes light harvesting efficiency. The electron transfer from selected dyes to the porous TiO₂ electrode is not only a favored process but is also much faster than other recombination processes, making porous TiO₂ an indispensable photo anode for DSC. In addition, mesoporous TiO₂ participates in light scattering, thus improving the photocurrent.

FIG. 2 is a diagram depicting electron and hole transport processes in a perovskite sensitized TiO₂ solar cell (prior art). The basic working principle of the perovskite-based solar cell is somewhat similar to the conventional solid state DSCs (ssDSCs). Excitons are generated within the organic/inorganic perovskite material by absorbing light of the appropriate wavelength. The electrons are then injected into the conduction band of the mesoporous TiO₂ framework, provided the lifetime of the excitons is long enough. The electrons migrate toward the electrode through diffusion. Subsequently, the positive charge travels through the perovskite and then is extracted by the HTM and delivered to the positive electrode. Such charge manipulation is accomplished through the selection of materials having proper band offsets, which helps to direct the charges to the appropriate material. Note: “hv” stands for one photon of light.

Despite the remarkable photovoltaic performances that have been demonstrated for the perovskite cells, a PCE as high as 15%, a number of issues remained. One of the challenges is related to the overall devices stability, especially the decomposition of the perovskite material in the presence of moisture and light, or the combination these effects. In addition, the crystallization of the perovskite material on the TiO2 surface is random, thus leading to polycrystallinity and potential problems with grain boundaries. Moisture can be effectively blocked through appropriate packaging of the solar cell. However, the problem of perovskite decomposition at the TiO₂/perovskite interface remains (Nature Comm., 2013, 4, 2885). This is because the perovskite-to-TiO₂ contact is different from that of dye-to-TiO₂, although the perovskite cell is a natural extension of ssDSC and the electron injection process remains preferred. In recent work (Science, 2012, 338 (6107), 643), a mesoporous network of the aluminum oxide was used as a scaffold for the perovskite structure. The cell performed better than that with the TiO₂ mesoporous network. The open circuit voltage was noticeably higher for Al₂O₃ than TiO₂, suggesting that there was less charge recombination in Al₂O₃. In this case, the transport of the negative charges occurs through the network of the perovskite material, as injection of electron into Al₂O₃ is energetically unfavorable. This result implies that charge injection from perovskite to TiO₂ is energetically favorable, but the imperfections at the interface act as recombination centers and further affect the device stability. Therefore, a proper interface between the perovskite absorber layer and TiO₂ would not only improve cell performance by eliminating those recombination centers but also help to achieve long term stability in such devices.

It would be advantageous if the perovskite interface in a mesoporous structure solar cell could be improved to increase stability and reduce recombination centers.

### SUMMARY OF THE INVENTION

Disclosed herein is a solar cell where the mesoporous surfaces have been effectively passivated. The passivating molecules not only serve as anchors for perovskite to link onto, but also prevent its decomposition from occurring upon light irradiation. The requirements for selecting the effective anchoring agent are two-fold. First, the passivating molecules should have an affinity towards the perovskite structure or participate in the perovskite structure formation. The amine or ammonium group can facilitate the proper formation of the perovskite layer. Second, the other end of the passivating molecule should have an affinity towards the mesoporous metal oxide surface, so that it is capable of providing good passivation for all the trap sites on the surface of the metal oxide. Aminosilanes or aminosiloxanes perform such a function. These two active ends can be connected via an organic hydrocarbon chain, and the length of the organic chain also controls the electron transfer/injection efficiency from the perovskite into the mesoporous metal oxide.

Accordingly, a method is provided for forming a mesoporous-structured solar cell with a silane or siloxane barrier. The method forms a transparent conductive electrode overlying a transparent substrate. A non-mesoporous layer of a first metal oxide overlies the transparent conductive electrode, with a mesoporous layer of a second metal oxide overlying the non-mesoporous layer of first metal oxide. An aminoalkoxysilane layer overlies the mesoporous layer of second metal oxide. Over the aminoalkoxysilane layer is deposited a semiconductor absorber layer prepared from organic and inorganic precursors. Using the aminoalkoxysilane, the mesoporous layer of second metal oxide is linked to the semiconductor absorber layer. A hole-transport material (HTM) layer is formed overlying the semiconductor absorber layer, and a metal electrode overlies the HTM layer.

More explicitly, depositing the aminoalkoxysilane layer includes the aminoalkoxysilane having a structure comprising A-L-B;

where B is a derivative of amino or ammonium;

where “A” is represented with a formula Si(OR)₃,
with R being a hydrogen atom, or a derivative of linear alkanes, branched alkanes, cycloalkanes, (poly)cycloalkanes, cis- and trans-linear alkenes, cis- and trans-branched alkenes, linear alkynes, branched alkynes, (poly)alkynes, aromatic hydrocarbons, (poly)aromatic hydrocarbons, heteroarenes, (poly)heteroarenes, thiophenes, (poly)thiophenes, (poly)anilines, or combination of above-recited elements; and,

where L is a derivative of linear alkanes, branched alkanes, cycloalkanes, (poly)cycloalkanes, cis- and trans-linear alkenes, cis- and trans-branched alkenes, linear alkynes, branched alkynes, (poly)alkynes, aromatic hydrocarbons, (poly)aromatic hydrocarbons, heteroarenes, (poly)heteroarenes, thiophenes, (poly)thiophenes, (poly)anilines, or combination of above-recited elements.

Some examples of the first and second metal oxides, which may be the same or different material, include titanium oxide (TiO₂), tin oxide (SnO₂), zinc oxide (ZnO), niobium oxide (Nb₂O₅), tantalum oxide (Ta₂O₅), barium titanate (BaTiO₃), strontium titanate (SrTiO₃), zinc titanate (ZnTiO₃), and copper titanate (CuTiO₃). The HTM layer may be an organic HTM material such as spiro-OMeTAD.

The semiconductor absorber layer has the general formula of FEX_{Z}Y_{3-Z};

where F is an organic monocation;

where E is a transition metal dication;

where X and Y are inorganic monoanions; and,

where Z is in a range of 0 to 1.5.

Additional details of the above-described method, a mesoporous-structured solar cell with a silane or siloxane barrier, and a related composite material are presented below.

### BRIEF DESCRIPTION OF THE DRAWINGS

FIG. 1 is a partial cross-sectional view of a perovskite solar cell structure (prior art).

FIG. 2 is a diagram depicting electron and hole transport processes in a perovskite sensitized TiO₂ solar cell (prior art).

FIG. 3 is a partial cross-sectional view depicting a mesoporous-structured solar cell with a silane or siloxane barrier.

FIGS. 4A through 4D are examples of aminoalkoxysilane linking molecules.

FIG. 5 is a flowchart illustrating an exemplary solar cell fabrication process using titanium oxide as the mesoporous metal oxide and perovskite as the semiconductor absorber.

FIG. 6 is a flowchart illustrating method for forming a mesoporous-structured solar cell with a silane or siloxane barrier.

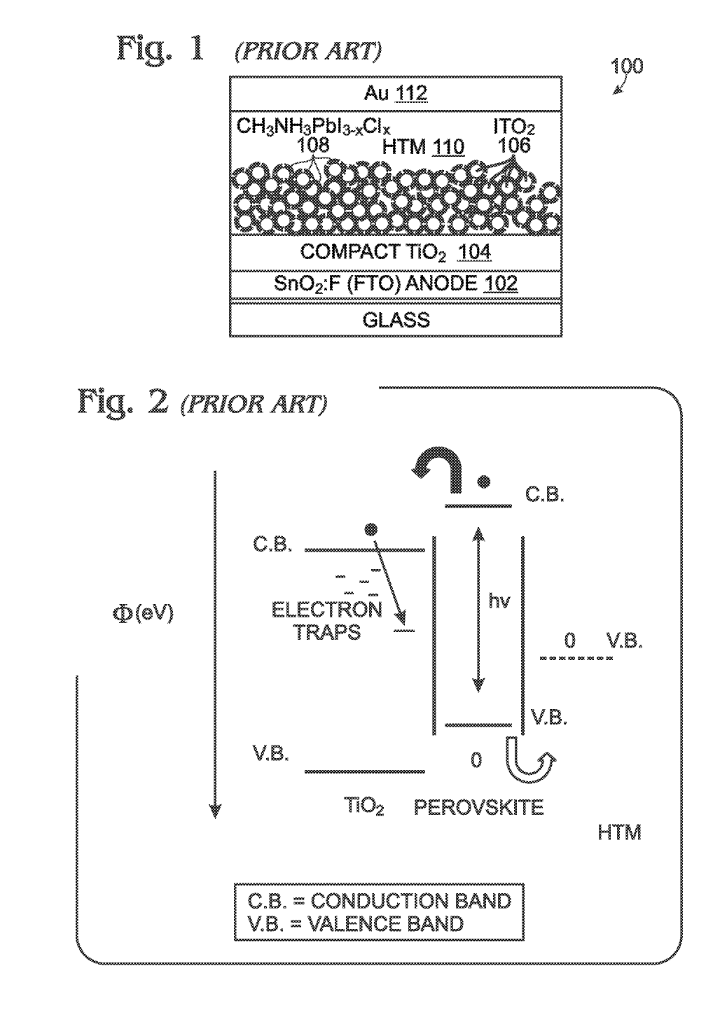

### DETAILED DESCRIPTION

FIG. 3 is a partial cross-sectional view depicting a mesoporous-structured solar cell with a silane or siloxane barrier. The solar cell 300 comprises a transparent substrate 302. Silica (glass), quartz, or a plastic may be used as the transparent substrate 302. A transparent conductive electrode 304 overlies the transparent substrate 302. Fluorine-doped tin oxide (SnO₂:F) can be used as the transparent conductive electrode 304. Forms of graphene, indium tin oxide (ITO), indium gallium zinc oxide (IGZO), other conductive metal oxides, and single-walled carbon nanotubes may also possibly be used as a transparent conductive electrode material. A non-mesoporous layer of a first metal oxide 306 overlies the transparent conductive electrode 304. A mesoporous layer of a second metal oxide 308 overlies the non-mesoporous layer of first metal oxide 306. A mesoporous material is a material containing pores with diameters between 2 and 100 nanometers (nm).

Generally, the first metal oxide 306 and second metal oxide 308 are both n-type metal oxides. More explicitly, the first metal oxide 306 and second metal oxide 308 are independently selected, meaning they may be the same or a different material, examples of which include titanium oxide (TiO₂), tin oxide (SnO₂), zinc oxide (ZnO), niobium oxide (Nb₂O₅), tantalum oxide (Ta₂O₅), barium titanate (BaTiO₃), strontium titanate (SrTiO₃), zinc titanate (ZnTiO₃), and copper titanate (CuTiO₃). This is not an exhaustive list of possible metal oxides.

A semiconductor absorber layer 310 overlies the mesoporous layer of second metal oxide 308, comprising organic and inorganic components. An aminoalkoxysilane linker 312 links the semiconductor absorber layer 310 to the mesoporous layer of second metal oxide 308. A hole-transport material (HTM) layer 314 overlies the semiconductor absorber layer 310, and a metal electrode 316 overlies the HTM layer 314. Typically, the HTM layer 314 is an organic HTM material such as spiro-OMeTAD. However, the solar cell is not limited to any particular HTM material. The metal electrode 316 may be a highly conductive metal such as silver, aluminum, copper, molybdenum, nickel, gold, or platinum. Note: the drawing is not to scale.

The aminoalkoxysilane linker 312 has a structure comprising (—O)ₓ—Si(OR)₃₋ₓ-L-NR′₃;
where R and R′ are independently selected (may be the same or different) from a group including a hydrogen atom, and derivatives of linear alkanes, branched alkanes, cycloalkanes, (poly)cycloalkanes, cis- and trans-linear alkenes, cis- and trans-branched alkenes, linear alkynes, branched alkynes, (poly)alkynes, aromatic hydrocarbons, (poly)aromatic hydrocarbons, heteroarenes, (poly)heteroarenes, thiophenes, (poly)thiophenes, (poly)anilines, and combination of above-recited elements.

L is typically a derivative of linear alkanes, branched alkanes, cycloalkanes, (poly)cycloalkanes, cis- and trans-linear alkenes, cis- and trans-branched alkenes, linear alkynes, branched alkynes, (poly)alkynes, aromatic hydrocarbons, (poly)aromatic hydrocarbons, heteroarenes, (poly)heteroarenes, thiophenes, (poly)thiophenes, (poly)anilines, or combination of above-recited elements, and X is in the range of 1 to 3. In form of a linker, the aminoalkoxysilane is typically ammonium, but prior to linking it may have been either amino or ammonium. Upon attachment to the metal oxide surface and hydrolysis, the “OR” moieties are completely or partially lost. With TiO₂ for example, the final linking would be Ti—O—Si. The other oxygen may participate in cross-linking, forming a secondary siloxane Si—O—Si structure. A siloxane is a functional group in organosilicon chemistry with the Si—O—Si linkage. The parent siloxanes include the oligomeric and polymeric hydrides with the formulae H(OSiH₂)ₙOH and (OSiH₂)ₙ. Siloxanes also include branched compounds, the defining feature being that each pair of silicon centers is separated by one oxygen atom.

The semiconductor absorber layer 310 has the general formula of FEX_{Z}Y_{3-Z};
where F is an organic monocation;
where E is a transition metal dication;

where X and Y are inorganic monoanions; and,

where Z is in a range of 0 to 1.5.

The organic monocation F may be a substituted ammonium cation with the general formula of D¹D²D³D⁴N;

where D may be hydrogen, or compounds derived from linear alkanes, branched alkanes, cycloalkanes, (poly)cycloalkanes, cis- and trans-linear alkenes, cis- and trans-branched alkenes, linear alkynes, branched alkynes, (poly)alkynes, aromatic hydrocarbons, (poly)aromatic hydrocarbons, heteroarenes, (poly)heteroarenes, thiophenes, (poly)thiophenes, (poly)anilines, or combination of above-recited elements;

where dication E may be Pb²⁺, Sn²⁺, Cu²+, Ge²+, Zn²⁺, Ni²⁺, Fe²⁺, Mn²⁺, Eu²⁺, or Co²+; and,

where the monoanions X and Y are independently selected from a group consisting of cyanides, thiocyanides, and halogenides including F—, Cl—, Br—, and I—. For example, the semiconductor absorber layer 310 may be CH₃NH₃Pbl_{3-X}Cl_{X}.

In one aspect, the combination of the second metal oxide layer 308, semiconductor absorber layer 310, and aminoalkoxysilane linker 312 may be considered to be composite material 318.

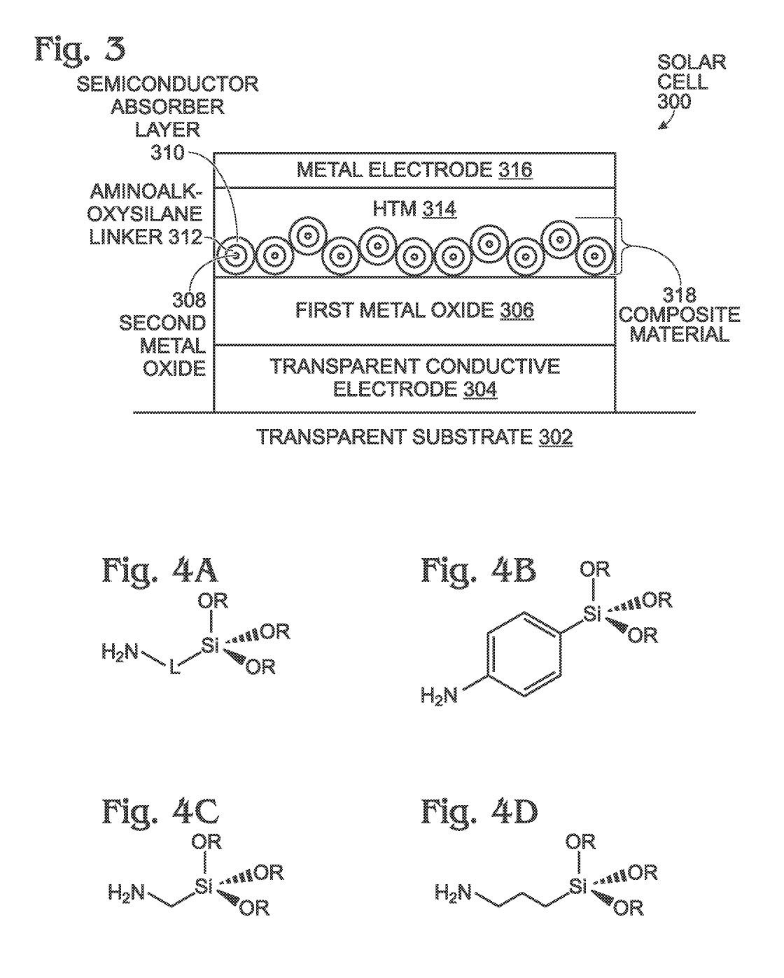

FIGS. 4A through 4D are examples of aminoalkoxysilane linking molecules. The aminoalkoxysilane linker acts as a unique means of modifying and passivating the surfaces of a mesoporous metal oxide, such as TiO₂ nanoparticles. The passivating molecules link to the semiconductor absorber layer (e.g., perovskite) and prevent decomposition from occurring upon light irradiation. The aminoalkoxysilane linker has an affinity to both the semiconductor absorber and the mesoporous metal oxide, providing good passivation for the trap sites on the mesoporous surface. Siloxanes (Si—O—Si) or silanes formed on a metal oxide surface have two active ends can be connected via an organic hydrocarbon chain. The length of the organic chain controls the electron transfer/injection efficiency from the semiconductor absorber into the mesoporous metal oxide. Silane, SiH₄, may also refer to many compounds containing silicon, such as trichlorosilane (SiHCl₃) and tetramethylsilane (Si(CH₃)₄). Alkoxysilane refers to alkoxy derivatives of silane—where hydrogen in the parent silane is substituted with an alkoxy group. FIG. 4A depicts the general formula of aminoalkoxysilane, FIG. 4B is 4-aminophenyl alkoxysilane, FIG. 4C is aminomethyl alkoxysilane, and FIG. 4D is aminopropyl alkoxy silane.

The general structure of such passivating-linker can have structures like: A-L-B, where “A” and B represent the functional aforementioned ends, and L represents the bridging group between the two functional ends. In particular, the group B may represent an amino or ammonium group; while group A can have a general formula such as Si(OR)₃, in which the R group can be alkyl, unsaturated, and substituted or unsubstituted hydrocarbon (or modified with heteroatoms) moiety. The part L can be comprised of saturated, unsaturated or aromatic hydrocarbon molecules. Their length dictates the efficiency of the electron injection from semiconductor absorber to mesoporous metal oxide (e.g., perovskite to TiO₂).

The coating of such a passivating material over mesoporous TiO₂ nanoparticle network can be carried out by dipping the TiO₂ substrate into diluted solution of siloxane followed by the exposure to air with optional heat treatment. This dip treatment only adds one extra step in the standard process flow of fabricating perovskite cells. Other solution-based methods could also be applied for the treatment of a metal oxide surface with the linker solution.

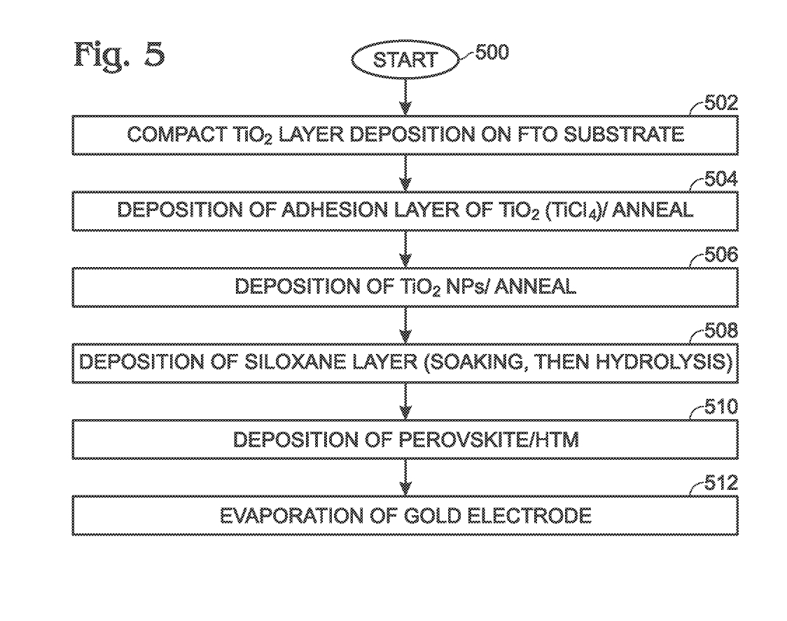

FIG. 5 is a flowchart illustrating an exemplary solar cell fabrication process using titanium oxide as the mesoporous metal oxide and perovskite as the semiconductor absorber. The method starts at Step 500 and in Step 502 a compact (i.e. planar or non-mesoporous) layer of (first) metal oxide is deposited on FTO. In Step 504 an adhesion layer of TiCl₄ is deposited, followed by annealing. In Step 506 titanium oxide nanoparticles (NPs) are deposited to form the mesoporous second oxide layer, followed by an annealing. In Step 508 a siloxane or silane layer is formed by dipping in a solution, followed by hydrolysis to remove water. In Step 510 the perovskite and HTM layers are formed, followed by a metal electrode in Step 512. In general, the treatment of Step 508 provides for coverage of the surface trap sites of titanium dioxide, as well as providing anchoring groups for further attachment of the organic/inorganic perovskite material in Step 510. There is no change in the perovskite material deposition process from conventional processes. The perovskite is deposited through conventional methods, such as spin-coating or physical deposition. The spin-coating solution can be a mixture of the precursors (ammonium salt and lead halogenides) or a single compound of lead halogenides followed by dipping in the solution of ammonium precursor.

The approach illustrated in FIG. 5 uses the advantages of a mesoporous metal oxide (e.g., TiO₂) structure, which is a mature standard dye-sensitized solar cell (DSC) process, and a quick simple dip coating process to form a layer of passivating material. Thus, the device combines the advantages of structure and passivation. In other words, a solution-based passivating semiconductor coating step is simply added to the already existing perovskite solar cell process flow after the formation of the mesoporous metal oxide.

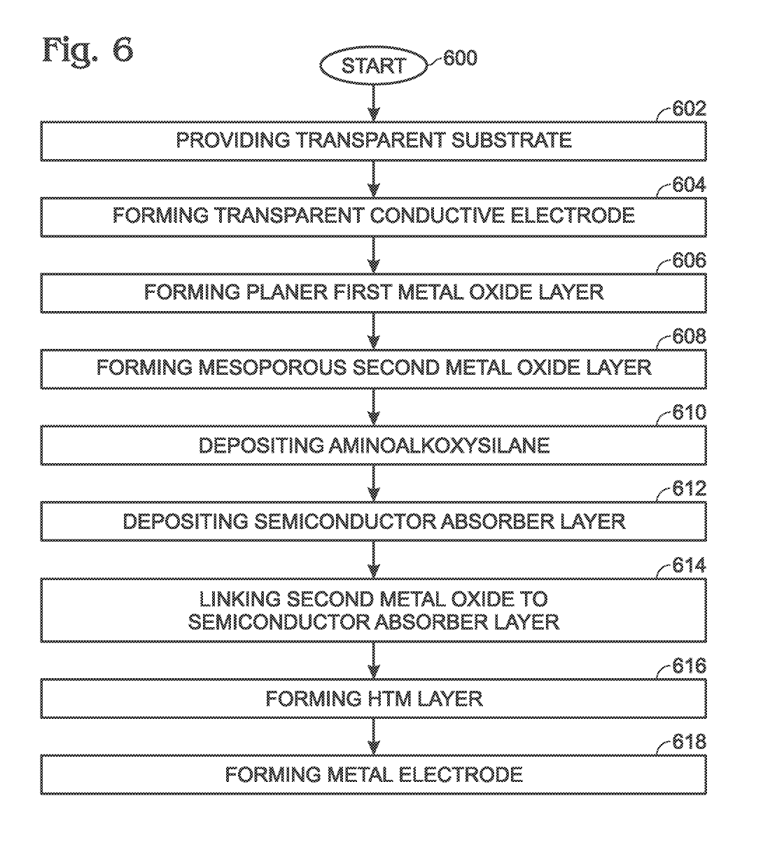

FIG. 6 is a flowchart illustrating method for forming a mesoporous-structured solar cell with a siloxane or silane barrier. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. Generally however, the method follows the numeric order of the depicted steps. The method starts at Step 600.

Step 602 forms a transparent substrate, and Step 604 forms a transparent conductive electrode overlying the transparent substrate, which may be FTO, ITO, or IGZO, to name a few examples. Step 606 forms a non-mesoporous layer of a first metal oxide overlying the transparent conductive electrode. Step 608 forms a mesoporous layer of a second metal oxide overlying the non-mesoporous layer of first metal oxide. Step 610 deposits an aminoalkoxysilane layer overlying the mesoporous layer of second metal oxide. Step 612 deposits a semiconductor absorber layer, comprising organic and inorganic components, overlying the aminoalkoxysilane layer. Using the aminoalkoxysilane, Step 614 links the mesoporous layer of second metal oxide to the semiconductor absorber layer. Step 616 forms a HTM layer overlying the semiconductor absorber layer. Step 618 forms a metal electrode overlying the HTM layer. Generally, the method illustrated in FIG. 6 describes the fabrication of the device shown in FIG. 3, and the examples of possible materials, listed above, are not repeated here in the interest of brevity.

Depositing the aminoalkoxysilane layer in Step 610 includes the aminoalkoxysilane linker having a structure comprising A-L-B;

where B is a derivative of amino or ammonium;

where “A” is represented with a formula Si(OR)₃,
with R being a hydrogen atom, or a derivative of linear alkanes, branched alkanes, cycloalkanes, (poly)cycloalkanes, cis- and trans-linear alkenes, cis- and trans-branched alkenes, linear alkynes, branched alkynes, (poly)alkynes, aromatic hydrocarbons, (poly)aromatic hydrocarbons, heteroarenes, (poly)heteroarenes, thiophenes, (poly)thiophenes, (poly)anilines, or a combination of above-recited elements; and,

where L is a derivative of linear alkanes, branched alkanes, cycloalkanes, (poly)cycloalkanes, cis- and trans-linear alkenes, cis- and trans-branched alkenes, linear alkynes, branched alkynes, (poly)alkynes, aromatic hydrocarbons, (poly)aromatic hydrocarbons, heteroarenes, (poly)heteroarenes, thiophenes, (poly)thiophenes, (poly)anilines, or a combination of above-recited elements. Upon attachment to the metal oxide surface and hydrolysis, the “OR” part is partially or completely lost. With, for example TiO₂, the final linking would be Ti—O—Si.

Amines are organic compounds and functional groups that contain a basic nitrogen atom with a lone pair. Amines are derivatives of ammonia, wherein one or more hydrogen atoms have been replaced by a substituent such as an alkyl or aryl group. Important amines include amino acids, biogenic amines, trimethylamine, and aniline. Inorganic derivatives of ammonia are also called amines, such as chloramine (NClH₂). Ammonia is a compound of nitrogen and hydrogen with the formula NH₃. The ammonium cation is a positively charged polyatomic ion with the chemical formula NH₄⁺. It is formed by the protonation of ammonia (NH₃). Ammonium is also a general name for positively charged or protonated substituted amines and quaternary ammonium cations (NR₄⁺), where one or more hydrogen atoms are replaced by organic radical groups (indicated by R).

The first and second metal oxides are independently selected from a group including titanium oxide (TiO₂), tin oxide (SnO₂), zinc oxide (ZnO), niobium oxide (Nb₂O), tantalum oxide (Ta₂Or), barium titanate (BaTiO₃), strontium titanate (SrTiO₃), zinc titanate (ZnTiO₃), and copper titanate (CuTiO₃). Forming the HTM layer in Step 616 includes forming an organic HTM material layer, such as spiro-OMeTAD.

Forming the semiconductor absorber layer in Step 612 includes forming a semiconductor absorber having a general formula of FEX_{Z}Y_{3-Z};

where F is an organic monocation;

where E is a transition metal dication;

where X and Y are inorganic monoanions; and,

where Z is in a range of 0 to 1.5.

A mesoporous-structured solar call using an aminoalkoxysilane barrier and associated fabrication processes have been provided. Examples of particular materials and process steps have been presented to illustrate the invention. However, the invention is not limited to merely these examples. Other variations and embodiments of the invention will occur to those skilled in the art.

We claim:

1. A mesoporous-structured solar cell with a silane or siloxane barrier, the solar cell comprising:
a transparent substrate;
a transparent conductive electrode overlying the transparent substrate;
a non-mesoporous layer of a first metal oxide overlying the transparent conductive electrode;
a mesoporous layer of a second metal oxide overlying the non-mesoporous layer of first metal oxide;
a semiconductor absorber layer overlying the mesoporous layer of second metal oxide, comprising organic and inorganic components;
an aminoalkoxysilane linker linking the semiconductor absorber layer to the mesoporous layer of second metal oxide;
a hole-transport material (HTM) layer overlying the semiconductor absorber layer; and,
a metal electrode overlying the HTM layer.

2. The solar cell of claim 1 wherein the aminoalkoxysilane linker has a structure comprising (—O)ₓ—Si(OR)₃₋ₓ-L-NR′₃;
where R and R′ are independently selected from a group consisting of a hydrogen atom, and derivatives of linear alkanes, branched alkanes, cycloalkanes, (poly)cycloalkanes, cis- and trans-linear alkenes, cis- and trans-branched alkenes, linear alkynes, branched alkynes, (poly)alkynes, aromatic hydrocarbons, (poly)aromatic hydrocarbons, heteroarenes, (poly)heteroarenes, thiophenes, (poly)thiophenes, (poly)anilines, and combination of above-recited elements;
where L is selected from a group consisting of derivatives of linear alkanes, branched alkanes, cycloalkanes, (poly)cycloalkanes, cis- and trans-linear alkenes, cis- and trans-branched alkenes, linear alkynes, branched alkynes, (poly)alkynes, aromatic hydrocarbons, (poly)aromatic hydrocarbons, heteroarenes, (poly)heteroarenes, thiophenes, (poly)thiophenes, (poly)anilines, and combination of above-recited elements; and,
where X is in a range of 1 to 3.

3. The solar cell of claim 1 wherein the first and second metal oxides are independently selected from a group consisting of titanium oxide (TiO₂), tin oxide (SnO₂), zinc oxide (ZnO), niobium oxide (Nb₂O₅), tantalum oxide (Ta₂O₅), barium titanate (BaTiO₃), strontium titanate (SrTiO₃), zinc titanate (ZnTiO₃), and copper titanate (CuTiO₃).

4. The solar cell of claim 1 wherein the HTM layer is an organic HTM material.

5. The solar cell of claim 4 wherein the HTM layer is spiro-OMeTAD.

6. The solar cell of claim 1 wherein the semiconductor absorber layer has a general formula of FEX_{Z}Y_{3-Z};
where F is an organic monocation;
where E is a transition metal dication;
where X and Y are inorganic monoanions; and,
where Z is in a range of 0 to 1.5.

7. The solar cell of claim 6 wherein the organic monocation F is selected from a group consisting of substituted ammonium cations with the general formula of D¹D²D³D⁴N;
where D is selected from a group consisting of hydrogen, and compounds derived from linear alkanes, branched alkanes, cycloalkanes, (poly)cycloalkanes, cis- and trans-linear alkenes, cis- and trans-branched alkenes, linear alkynes, branched alkynes, (poly)alkynes, aromatic hydrocarbons, (poly)aromatic hydrocarbons, heteroarenes, (poly)heteroarenes, thiophenes, (poly)thiophenes, (poly)anilines, and combination of above-recited elements;
wherein dication E is selected from could be selected from Pb²⁺, Sn²⁺, Cu²+, Ge²+, Zn²⁺, Ni²⁺, Fe²⁺, Mn²⁺, Eu^{2+,} and Co²+; and,
wherein the monoanions X and Y are independently selected from a group consisting of cyanides, thiocyanides, and halogenides including F—, Cl—, Br—, and I—.

8. The solar cell of claim 6 wherein the semiconductor absorber layer is CH₃NH₃Pbl_{3-X}Cl_{X}.

9. The solar cell of claim 1 wherein the first and second metal oxides are n-type metal oxides.

10. A method for forming a mesoporous-structured solar cell with a silane or siloxane barrier, the method comprising:
forming a transparent substrate;
forming a transparent conductive electrode overlying the transparent substrate;
forming a non-mesoporous layer of a first metal oxide overlying the transparent conductive electrode;
forming a mesoporous layer of a second metal oxide overlying the non-mesoporous layer of first metal oxide;
depositing an aminoalkoxysilane layer overlying the mesoporous layer of second metal oxide;
depositing a semiconductor absorber layer, comprising organic and inorganic components, overlying the aminoalkoxysilane layer;
using the aminoalkoxysilane, linking the mesoporous layer of second metal oxide to the semiconductor absorber layer;
forming a hole-transport material (HTM) layer overlying the semiconductor absorber layer; and,
forming a metal electrode overlying the HTM layer.

11. The method of claim 10 wherein depositing the aminoalkoxysilane layer includes the aminoalkoxysilane having a structure comprising A-L-B;
where B is selected from a group consisting of derivatives of amino and ammonium;
where “A” is represented with a formula Si(OR)₃,
with R being selected from a group consisting of a hydrogen atom, and derivatives of linear alkanes, branched alkanes, cycloalkanes, (poly)cycloalkanes, cis- and trans-linear alkenes, cis- and trans-branched alkenes, linear alkynes, branched alkynes, (poly)alkynes, aromatic hydrocarbons, (poly)aromatic hydrocarbons, heteroarenes, (poly)heteroarenes, thiophenes, (poly)thiophenes, (poly)anilines, and combination of above-recited elements; and,
where L is selected from a group consisting of derivatives of linear alkanes, branched alkanes, cycloalkanes, (poly)cycloalkanes, cis- and trans-linear alkenes, cis- and trans-branched alkenes, linear alkynes, branched alkynes, (poly)alkynes, aromatic hydrocarbons, (poly)aromatic hydrocarbons, heteroarenes, (poly)heteroarenes, thiophenes, (poly)thiophenes, (poly)anilines, and combination of above-recited elements.

12. The method of claim 10 wherein the first and second metal oxides are independently selected from a group consisting of titanium oxide (TiO₂), tin oxide (SnO₂), zinc oxide (ZnO), niobium oxide (Nb₂O₅), tantalum oxide (Ta₂O₅), barium titanate (BaTiO₃), strontium titanate (SrTiO₃), zinc titanate (ZnTiO₃), and copper titanate (CuTiO₃).

13. The method of claim 10 wherein forming the HTM layer includes forming an organic HTM material layer.

14. The method of claim 10 wherein forming the semiconductor absorber layer includes forming a semiconductor absorber having a general formula of FEX_{Z}Y_{3-Z};
where F is an organic monocation;
where E is a transition metal dication;
where X and Y are inorganic monoanions; and,
where Z is in a range of 0 to 1.5.

15. A composite material comprising:
a layer of a metal oxide;
a semiconductor absorber layer, comprising organic and inorganic components, overlying the layer of metal oxide; and,
an aminoalkoxysilane linker, linking the layer of metal oxide to the semiconductor absorber layer.

16. The composite material of claim 15 wherein the layer of metal oxide is a layer of mesoporous metal oxide.

17. The composite material of claim 15 wherein the aminoalkoxysilane linker has a structure comprising A-L-B;
where B is linked to the semiconductor absorber layer and selected from a group consisting of derivatives of amino and ammonium;
where “A” is linked to the layer of metal oxide and represented with a formula Si(OR)₃,
with R being selected from a group consisting of a hydrogen atom, and derivatives of linear alkanes, branched alkanes, cycloalkanes, (poly)cycloalkanes, cis- and trans-linear alkenes, cis- and trans-branched alkenes, linear alkynes, branched alkynes, (poly)alkynes, aromatic hydrocarbons, (poly)aromatic hydrocarbons, heteroarenes, (poly)heteroarenes, thiophenes, (poly)thiophenes, (poly)anilines, and combination of above-recited elements, and hydrocarbon moieties modified with heteroatoms; and,
where L is selected from a group consisting of derivatives of linear alkanes, branched alkanes, cycloalkanes, (poly)cycloalkanes, cis- and trans-linear alkenes, cis- and trans-branched alkenes, linear alkynes, branched alkynes, (poly)alkynes, aromatic hydrocarbons, (poly)aromatic hydrocarbons, heteroarenes, (poly)heteroarenes, thiophenes, (poly)thiophenes, (poly)anilines, and combination of above-recited elements.

18. The composite material of claim 15 wherein the metal oxide is selected from a group consisting of titanium oxide (TiO₂), tin oxide (SnO₂), zinc oxide (ZnO), niobium oxide (Nb₂O₅), tantalum oxide (Ta₂O₅), barium titanate (BaTiO₃), strontium titanate (SrTiO₃), zinc titanate (ZnTiO₃), and copper titanate (CuTiO₃).
